(19) United States
(12) Patent Application Publication
(10) Pub. No.: US 2025/0089527 A1
(43) Pub. Date: Mar. 13, 2025

(54) DISPLAY MODULE AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Han ZHANG, Beijing (CN); Danyang BI, Beijing (CN); Xiaoliang FU, Beijing (CN); Yi ZHANG, Beijing (CN); Wei GONG, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/290,451

(22) PCT Filed: Nov. 29, 2022
(86) PCT No.: PCT/CN2022/135177

§ 371 Date: Nov. 14, 2023

(51) Int. Cl. H10K 59/80; H10K 102/00

(52) U.S. Cl. CPC H10K 59/873; H10K 2102/311

(57) ABSTRACT

Provided is a display module. The display module includes a protective cover plate and a flexible display panel. The protective cover plate includes a body portion in a shape of a circular plate and a bent portion disposed around the body portion, the bent portion being fixedly connected to an edge of the body portion; and a light exit side of the flexible display panel faces the protective cover plate, and the flexible display panel includes a first panel portion attached to the body portion and a second panel portion disposed around the first panel portion, an orthographic projection of the second panel portion on the protective cover plate being within the bent portion.

### CROSS-REFERENCE TO RELATED APPLICATIONS

This application is a U.S. national stage of international application No. PCT/CN2022/135177, filed on Nov. 29, 2022, the disclosure of which is herein incorporated by reference in its entirety.

### TECHNICAL FIELD

The present disclosure relates to the field of display technologies, and in particular, to a display module and a display device.

### BACKGROUND

At present, a display device is usually provided with a display module with a flexible display panel and a protective cover plate as a display. Relative to a conventional display panel, the flexible display panel has the advantages of being deformable, bendable, and more flexible.

### SUMMARY

Embodiments of the present application provide a display module and a display device. The technical solutions are as follows.

On the one hand, a display module is provided, the display module including:
a protective cover plate and a flexible display panel; wherein
the protective cover plate includes a body portion in a shape of a circular plate and a bent portion disposed around the body portion, the bent portion being fixedly connected to an edge of the body portion; and
a light exit side of the flexible display panel faces the protective cover plate, and the flexible display panel includes a first panel portion attached to the body portion and a second panel portion disposed around the first panel portion, an orthographic projection of the second panel portion on the protective cover plate being within the bent portion.

In some embodiments, a boundary of an orthographic projection of the first panel portion on the protective cover plate is coincident with a boundary of the body portion.

In some embodiments, both the bent portion and the second panel portion are annular.

In some embodiments, at least a part of the second panel portion is attached to the bent portion.

In some embodiments, the second panel portion includes a panel bending portion, and the flexible display panel further includes a third panel portion fixedly connected to a side, distal from the first panel portion, of the panel bending portion, the third panel portion being configured to be bonded to a drive assembly.

In some embodiments, the bent portion includes a first sub-bent portion and a second sub-bent portion, an extending direction of an arc surface, proximal to the flexible display panel, of the first sub-bent portion being curved, and an extending direction of an arc surface, proximal to the flexible display panel, of the second sub-bent portion being straight;
wherein an orthographic projection of the panel bending portion of the second panel portion on the protective cover plate is at least within the second sub-bent portion, and orthographic projections of other portions of the second panel portion on the protective cover plate are at least within the first sub-bent portion.

In some embodiments, a surface, distal from the body portion, of the first sub-bent portion is a first table surface, and a surface, distal from the body portion, of the second sub-bent portion is a second table surface, the first table surface being coplanar with the second table surface, and a width of the first table surface being smaller than a width of the second table surface.

In some embodiments, the width of the second table surface gradually decreases in a direction from center to ends of the second table surface.

In some embodiments, the bent portion further includes a transition portion disposed between the first sub-bent portion and the second sub-bent portion; wherein an arc surface, proximal to the flexible display panel, of the transition portion is tangential to the arc surface, proximal to the flexible display panel, of the first sub-bent portion and tangential to the arc surface, proximal to the flexible display panel, of the second sub-bent portion.

In some embodiments, an avoidance hole is defined in a side, facing the panel bending portion, of the second sub-bent portion.

In some embodiments, a width of the second panel portion ranges from 0.1 mm to 1 mm.

In some embodiments, the protective cover plate includes a central light-transmitting region and an edge shading region at a periphery of the central light-transmitting region, at least a part of the edge shading region being within the bent portion; and the display module further includes a light-absorbent ink layer on a side, proximal to the flexible display panel, of the protective cover plate, the light-absorbent ink layer being within the edge shading region.

In some embodiments, the display module further includes one or more first alignment structures secured to a side, distal from the protective cover plate, of the light-absorbent ink layer and one or more second alignment structures secured to a side, proximal to the protective cover plate, of the flexible display panel, the one or more first alignment structures being one-to-one correspondence to the one or more second alignment structures:
wherein the first alignment structure and the corresponding second alignment structure are configured to align the protective cover plate with the flexible display panel prior to attaching the protective cover plate to the flexible display panel.

In some embodiments, the first alignment structure is made of an ink material, and a color of the first alignment structure is different from a color of the light-absorbent ink layer.

In some embodiments, the flexible display panel includes a display region and a non-display region at a periphery of the display region, a boundary of an orthographic projection of the display region on the protective cover plate being coincident with a boundary of the central light-transmitting region; wherein
an orthographic projection of the non-display region on the protective cover plate is partially within the bent portion and partially within the body portion; or
the orthographic projection of the non-display region on the protective cover plate is entirely within the bent portion, and an orthographic projection of the display region on the protective cover plate is entirely within the body portion; or
the orthographic projection of the non-display region on the protective cover plate is entirely within the bent portion, and the orthographic projection of the display region on the protective cover is partially within the bent portion.

In some embodiments, in the case that the orthographic projection of the non-display region on the protective cover plate is entirely within the bent portion, and the orthographic projection of the display region on the protective cover is partially within the bent portion, a width of the part of the display region with the orthographic projection within the bent portion ranges from 0.1 mm to 0.2 mm.

In some embodiments, the protective cover plate includes a first mounting surface and a second mounting surface perpendicular to the first mounting surface; wherein
the first mounting surface is a surface, distal from the body portion, of the bent portion, and the second mounting surface is a side surface, distal from the flexible display panel, of the protective cover plate in a direction of a display surface of the flexible display panel;
wherein both the first mounting surface and the second mounting surface are configured for mounting to a housing.

In some embodiments, the first mounting surface is parallel to a surface, proximal to the first panel portion, of the body portion.

On the other hand, a display device is provided, the display device including:
a power supply assembly and a display module, wherein the display module is a display module defined in any one of the foregoing, and the power supply assembly is configured to supply power to the display module.

In some embodiments, in the case that the protective cover plate includes a first mounting surface and a second mounting surface, the display device further includes a housing, wherein an annular mounting groove is defined in the housing, and the mounting groove includes a bottom surface for connection to the first mounting surface and a side surface for connection to the second mounting surface.

### BRIEF DESCRIPTION OF DRAWINGS

To describe the technical solutions in the embodiments of the present disclosure more clearly, the following briefly describes the accompanying drawings required for describing the embodiments. Apparently, the accompanying drawings in the following description show merely some embodiments of the present disclosure, and a person skilled in the art may still derive other drawings from these accompanying drawings without creative efforts.

FIG. 1 is a schematic structural diagram of a display module according to the related art;

FIG. 2 is a schematic structural diagram of a display module according to embodiments of the present application;

FIG. 3 is an exploded schematic diagram of the display module shown in FIG. 2;

FIG. 4 is across-sectional view of a display module according to the embodiments of the present application;

FIG. 5 is a schematic diagram of an effect of a protective cover plate being attached to a flexible display panel according to the embodiments of the present application;

FIG. 6 is a cross-sectional view of the protective cover plate and the flexible display panel shown in FIG. 5;

FIG. 7 is another schematic diagram of an effect of a protective cover plate being attached to a flexible display panel according to the embodiments of the present application;

FIG. 8 is a cross-sectional view of the protective cover plate and the flexible display panel shown in FIG. 7;

FIG. 9 is a schematic structural diagram of a portion of a display module according to the embodiments of the present application;

FIG. 10 is another schematic structural diagram of a portion of a display module according to the embodiments of the present application:

FIG. 11 is another schematic structural diagram of a display module according to the embodiments of the present application;

FIG. 12 is an exploded schematic view of the display module shown in FIG. 11;

FIG. 13 is a top view of the display module shown in FIG. 12;

FIG. 14 is yet another schematic structural diagram of a display module according to the embodiments of the present application;

FIG. 15 is an exploded schematic view of the display module shown in FIG. 14;

FIG. 16 is an exploded schematic diagram of a display module according to the embodiments of the present application;

FIG. 17 is a schematic diagram of the distribution of a first alignment strip on a protective cover plate according to the embodiments of the present application:

FIG. 18 is another schematic diagram of the distribution of the first alignment strip on the protective cover plate according to the embodiments of the present application:

FIG. 19 is yet another schematic diagram of the distribution of the first alignment strip on the protective cover plate according to the embodiments of the present application;

FIG. 20 is still another schematic diagram of the distribution of the first alignment strip on the protective cover plate according to the embodiments of the present application;

FIG. 21 is a cross-sectional view of a display module according to the embodiments of the present application;

FIG. 22 is another cross-sectional view of a display module according to the embodiments of the present application;

FIG. 23 is yet another cross-sectional view of a display module according to the embodiments of the present application;

FIG. 24 is a schematic diagram of a film layer structure of a flexible display panel according to the embodiments of the present application;

FIG. 25 is a schematic diagram of a protective cover plate assembled with a housing according to the embodiments of the present application;

FIG. 26 is a front view of a support base for supporting a flexible display panel according to the embodiments of the present application;

FIG. 27 is a side view of the support base shown in FIG. 26;

FIG. 28 is a top view of the support base shown in FIG. 26;

FIG. 29 is a top view of a protective cover plate according to the embodiments of the present application;

FIG. 30 is a schematic diagram of a partial structure at A-A′ in FIG. 29;

FIG. 31 is another schematic diagram of a partial structure at A-A′ in FIG. 29;

FIG. 32 is another top view of a protective cover plate according to the embodiments of the present application;

FIG. 33 is a cross-sectional view along B-B′ in FIG. 29:

FIG. 34 is a cross-sectional view of a display device according to the embodiments of the present application.

Some specific embodiments of the present application are shown by means of the above-described accompanying drawings, which are described in detail hereinafter. These accompanying drawings and textual descriptions are not intended to limit, in any way, the scope of the conception of the present application, but rather to illustrate the concepts of the present application for those skilled in the art by reference to particular embodiments.

### DETAILED DESCRIPTION

In order to make the purpose, technical solutions, and advantages of the present application clearer, the following further describes the embodiments of the present application in detail in conjunction with the accompanying drawings.

In the related art, reference is made to FIG. 1, which is a schematic structural diagram of a display module according to the related art. The light exit side of the flexible display panel in the display module can be oriented toward the protective cover plate, the flexible display panel 10 in the display module is usually attached to a planar region of the protective cover plate 20, and the protective cover plate can protect the flexible display panel to some extent. However, in the case that the protective cover plate is attached to the flexible display panel, the space utilization for the curved region of the protective cover plate 20 is insufficient, which results in a wider overall bezel of the display module and a lower screen-to-body ratio of the display module, thereby hindering a narrow bezel design of the display module.

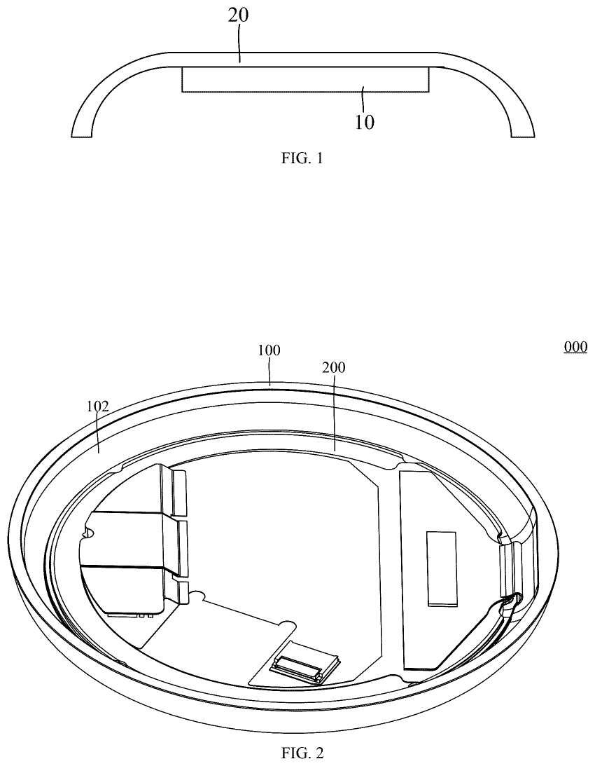

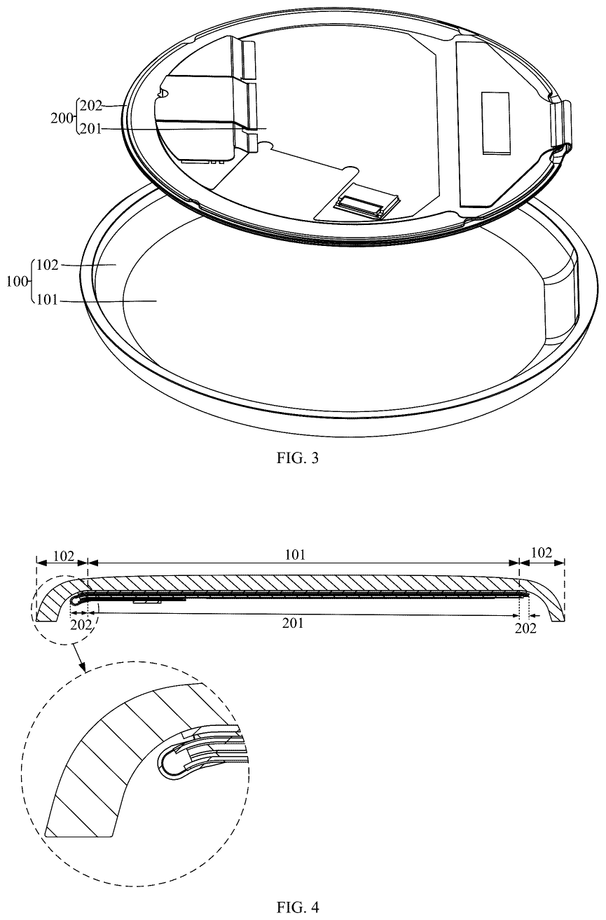

Referring to FIGS. 2 and 3, FIG. 2 being a schematic structural diagram of a display module according to embodiments of the present application, and FIG. 3 being an exploded schematic diagram of the display module shown in FIG. 2, the display module 000 includes a protective cover plate 100 and a flexible display panel 200.

In some embodiments, the protective cover plate 100 in the display module 000 includes a body portion 101 in a shape of a circular plate and a bent portion 102 disposed around the body portion 101, wherein the bent portion 102 is fixedly connected to an edge of the body portion 101.

Referring to FIG. 4, FIG. 4 being a cross-sectional view of a display module according to the embodiments of the present application, in some embodiments, a light exit side of the flexible display panel 200 in the display module 000 faces the protective cover plate 100, and the flexible display panel 200 includes a first panel portion 201 attached to the body portion 101 of the protective cover plate 100 and a second panel portion 202 disposed around the first panel portion 201. In some embodiments, an orthographic projection of the second panel portion 202 of the flexible display panel 200 on the protective cover plate 100 is within the bent portion 102 of the protective cover plate 100. In some embodiments, the flexible display panel 200 refers to a display panel capable of bending. In some embodiments, the flexible display panel 200 is a display panel that includes an organic electroluminescent device (such as an organic light-emitting diode (OLED)).

In the embodiments of the present application, the protective cover plate 100 in the display module 000 is disposed on the light exit side of the flexible display panel 200, the first panel portion 201 of the flexible display panel 200 is attached to the body portion 101 of the protective cover plate 100, and an orthographic projection of the second panel portion 202 on the protective cover plate 100 is within the bent portion 102 of the protective cover plate 100, therefore the second panel portion 202 of the flexible display panel 200 extends into the bent portion 102 of the protective cover plate 100. Thus, upon the flexible display panel 200 being attached to the protective cover plate 100, the acquired display module 000 has a narrower overall bezel, and the screen-to-body ratio of the display module 000 is larger, which can improve the user's experience. In addition, in the case that the display module 000 is integrated into the display device, the overall bezel of the display device is smaller, and the decoration effect for the display device is improved. The above technical solution can solve the problem of low screen-to-body ratio of the display module in the related art caused by the wide overall bezel of the display module.

In summary, the embodiments of the present application provide a display module. The display module includes a protective cover plate and a flexible display panel. The protective cover plate in the display module is disposed on the light exit side of the flexible display panel, a first panel portion of the flexible display panel is attached to a body portion of the protective cover plate, and an orthographic projection of a second panel portion on the protective cover plate is within a bent portion of the protective cover plate, therefore the second panel portion of the flexible display panel can extend into the bent portion of the protective cover plate. Therefore, upon the flexible display panel being attached to the protective cover plate, the acquired display module has a narrower overall bezel and a larger screen-to-body ratio, which improves the user's experience. In addition, in the case that the display module is integrated into the display device, the overall bezel of the display device is smaller and the decoration effect for the display device is improved.

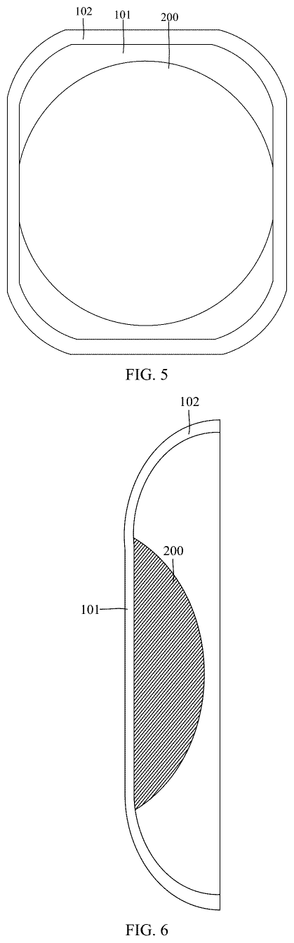

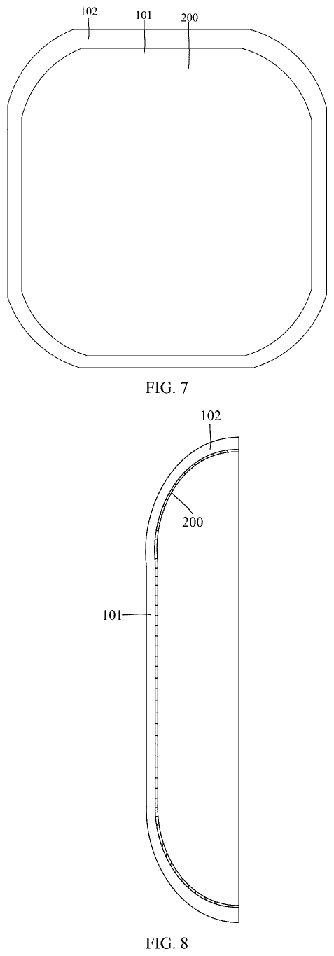

In some embodiments, as shown in FIG. 4, a boundary of the orthographic projection of the first panel portion 201 of the flexible display panel 200 on the protective cover plate 100 is coincident with a boundary of the body portion 101 of the protective cover plate 100. In this case, by making the boundary of the first panel portion 201 of the flexible display panel 200 coincident with the boundary of the body portion 101 of the protective cover plate 100 and making the first panel portion 201 attach to the body portion 101, and setting the shape of the boundary of the first panel portion 201 circular, the connection between the flexible display panel 200 and the body portion 101 of the protective cover plate 100 is more stable, thereby ensuring a better assembly yield of the display module 000. It is to be noted that among other possible implementations, please refer to FIG. 5 and FIG. 6, FIG. 5 being a schematic diagram of an effect of a protective cover plate being attached to a flexible display panel according to the embodiments of the present application, and FIG. 6 being a cross-sectional view of the protective cover plate and the flexible display panel shown in FIG. 5, the body portion 101 of the protective cover plate 100 has a square-shaped plate structure, the bent portion 102 is arc-shaped at four corners, and the flexible display panel 200 attached to the body portion 101 is circular. In some other embodiments, please refer to FIGS. 7 and 8. FIG. 7 being another schematic diagram of an effect of the protective cover plate being attached to the flexible display panel according to the embodiments of the present application, and FIG. 8 being a cross-sectional view of the protective cover plate and the flexible display panel shown in FIG. 7, the body portion 101 of the protective cover plate 100 has a square-shaped plate structure, the bent portion 102 is arc-shaped at four corners, and the flexible display panel 200 attached to the body portion 101 is square, which are not limited in the embodiments of the present application.

In the embodiments of the present application, as shown in FIGS. 3 and 4, both the bent portion 102 of the protective cover plate 100 and the second panel portion 202 of the flexible display panel 200 are in an annular shape. In this case, by setting the bent portion 102 of the protective cover plate 100 in an annular shape, the annular bent portion 102 matches the shape of the body portion 101 which is in the shape of a circular plate. Further, by setting the second panel portion 202 of the flexible display panel 2(x) in an annular shape, the shape of the annular second panel portion 202 matches the shape of the annularly shaped bent portion 102 of the protective cover plate 100. In this way, in the case that the orthographic projection of the second panel portion 202 of the flexible display panel 200 on the protective cover plate 100 is within the bent portion 102 of the protective cover plate 100, the appearance of the second panel portion 202 and the bent portion 102 upon being attached to each other is better, which improves user's experience.

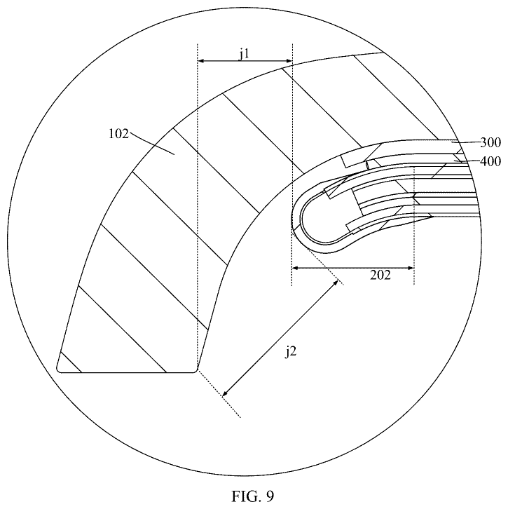

In some embodiments, referring to FIG. 9, which is a schematic structural diagram of a portion of a display module according to the embodiments of the present application, at least a portion of the second panel portion 202 of the flexible display panel 200 is attached to the bent portion 102 of the protective cover plate 100. In this case, by setting at least a portion of the second panel portion 202 being attached to the bent portion 102 of the protective cover plate 100, the connection between the flexible display panel 200 and the protective cover plate 100 is more stable. In some embodiments, a portion of the second panel portion 202 of the flexible display panel 200 is attached to the bent portion 102 of the protective cover plate 100; or, all of the second panel portion 202 is attached to the bent portion 102 of the protective cover plate 100 (i.e., the second panel portion is attached to the bent portion or the second panel portion is attached to the bent portion through other film layers). In some embodiments of the present application, the display module 000 further includes an optical adhesive (such as Optically Clear Adhesive (OCA)) layer 300 and a polarizer 400 disposed between the protective cover plate 100 and the flexible display panel 200, the optical adhesive layer 300 being configured to affix the flexible display panel 200 to the protective cover plate 100. In some embodiments, one side of the optical adhesive layer 300 is bonded to the protective cover plate 100, and the other side is bonded to the polarizer 400. The surface, distal from the optical adhesive layer 300, of the polarizer 400 is in contact with the flexible display panel 200. In some embodiments, an orthographic projection of the optical adhesive layer 300 on the protective cover plate 10 is partially within the bent portion 102 of the protective cover plate 100, and an orthographic projection of the polarizer 400 on the protective cover plate 100 is also partially within the bent portion 102 of the protective cover plate 100. The polarizer 400 can reduce the amount of external light emitted from the light exit surface of the flexible display panel 200 upon the external light entering inside the flexible display panel 200 and being reflected by the internal structure of the flexible display panel 200.

In some embodiments of the present application, referring to FIGS. 9 and 10, FIG. 10 being another schematic structural diagram of a portion of a display module according to the embodiments of the present application, the second panel portion 202 of the flexible display panel 200 includes a panel bending portion 2021, and the flexible display panel 200 further includes a third panel portion 203 fixedly connected to a side, distal from the first panel portion 201, of the panel bending portion 2021 of the second panel portion 202, which is configured to be bonded to a drive assembly (not shown in the figure). In this case, by performing a bending (such as pad bending) on the flexible display panel 200, the third panel portion 203 of the flexible display panel 200 is capable of binding to the drive assembly, which can reduce the bezel of the display module 000, and a narrow bezel design of the display module can be achieved. In the present application, the third panel portion 203 of the flexible display panel 200 is disposed at the back of the first panel portion 201 and is parallel to the first panel portion 201. In the case that the display module 000 is integrated into the display device, the third panel portion 203 is configured to be bonded to the drive assembly, such that the drive assembly drives the flexible display panel 200 in the display module 000 to display a screen. In some embodiments, the drive assembly includes a driver chip (such as a Driver Integrated Circuit (Driver IC)) and a circuit board (not shown in the figures).

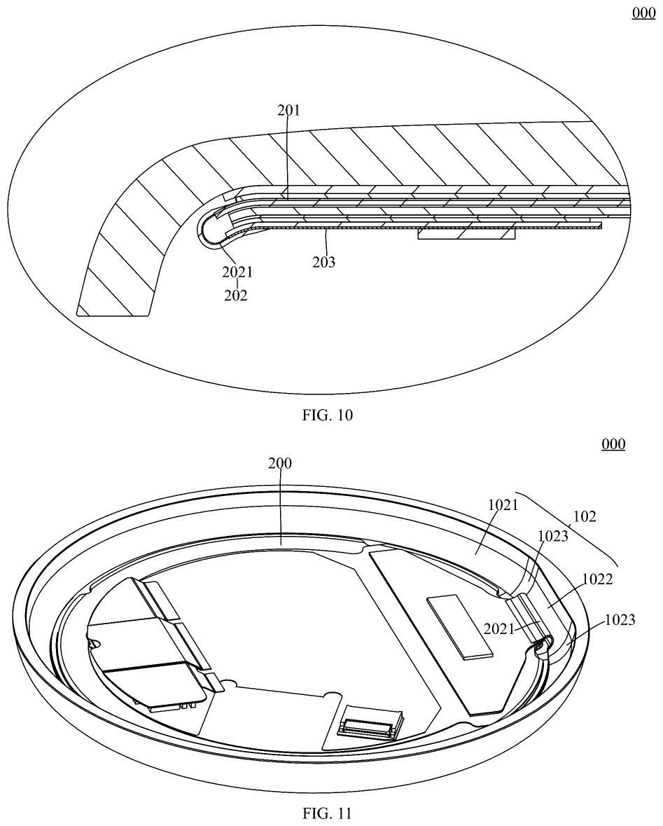

In some embodiments, referring to FIG. 10, FIG. 11, and FIG. 12, FIG. 11 being a schematic structural diagram of a display module according to the embodiments of the present application, and FIG. 12 being an exploded schematic diagram of the display module shown in FIG. 11, the bent portion 102 of the protective cover plate 100 includes a first sub-bent portion 1021 and a second sub-bent portion 1022, wherein an extension direction of arc surface a1, proximal to the flexible display panel 200, of the first sub-bent portion 1021 is curved, and an extension direction of arc surface a2, proximal to the flexible display panel 200, of the second sub-bent portion 1022 is straight. In some embodiments, an orthographic projection of the panel bending portion 2021 of the second panel portion 202 on the protective cover plate 100 is at least within the second sub-bent portion 1022, and orthographic projections of other portions of the second panel portion 202 on the protective cover plate 100 are at least within the first sub-bent portion 1021. In this case, by setting the extension direction of the arc surface a2, proximal to the flexible display panel 200, of the second sub-bent portion 1022 of the protective cover plate 100 being straight, in the case that the orthographic projection of the panel bending portion 2021 of the second panel section 202 on the protective cover plate 100 is within the second sub-bent portion 1022, the panel bending portion 2021 of the second panel section 202 is not subjected to circular bending compression. Therefore, the undesirable phenomenon of compression folds on the panel bending portion 2021 of the second panel section 202 is effectively reduced, and a better appearance of the panel bending portion 2021 of the second panel portion 202 is ensured. In some embodiments of the present application, the orthographic projection of the panel bending portion 2021 of the second panel section 202 on the protective cover plate 100 is entirely within the second sub-bent portion 1022 of the protective cover plate 100. This further ensures that the panel bending portion 2021 of the second panel section 202 is not subjected to the undesirable phenomenon of circular bending compression.

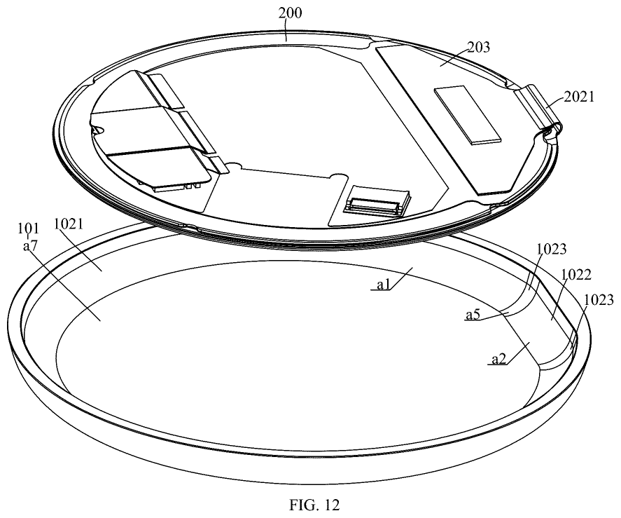

In the present application, reference is made to FIG. 12 and FIG. 13, FIG. 13 being a top view of the display module shown in FIG. 12. In the case that the orthographic projection of the panel bending portion 2021 of the second panel portion 202 on the protective cover plate 100 is entirely within the second sub-bent portion 1022, the orthographic projections of other portions of the second panel portion 202 on the protective cover plate 100 is within the first sub-bent portion 1021, and the orthographic projection of another portion of the second panel portion 202 on the protective cover plate 100 is within the second sub-bent portion 1022. In this way, in the case that the orthographic projection of the other portion of the second panel portion 202 on the protective cover plate 100 is within the second sub-bent portion 1022, the portion of the second panel portion 202 is bonding to the second sub-bent portion 1022 by the optical adhesive layer 300, which can effectively reduce the probability of generating air bubbles during the bonding process of the optical adhesive layer 300. In some embodiments, the arc surface a1, proximal to the flexible display panel 200, of the first sub-bent portion 1021 is circular, and the arc surface a2, proximal to the flexible display panel 200, of the second sub-bent portion 1022 is also circular.

In some embodiments of the present application, as shown in FIG. 13, a surface, distal from the body portion 101, of the first sub-bent portion 1021 of the protective cover plate 100 is a first table surface a3, and a surface, distal from the body portion 101, of the second sub-bent portion 1022 is a second table surface a4. In some embodiments, the first table surface a3 and the second table surface a4 are coplanar, and a width of the first table surface a3 is smaller than a width of the second table surface a4. In this case, by setting the first table surface a3, distal from the body portion 101, of the first sub-bent portion 1022 and the second table surface a4, distal from the body portion 101, of the second sub-bent portion 1022 of the protective cover plate 100 being coplanar, and the width of the first table surface a3 being smaller than the width of the second table surface a4, the arc surface a2, proximal to the flexible display panel 200, of the second sub-bent portion 1022 is cylindrical.

In some embodiments, as shown in FIG. 13, the width of the second table surface a4, distal from the body portion 101, of the second sub-bent portion 1022 gradually decreases in a direction from the center to the ends of the second table surface a4.

In some embodiments of the present application, as shown in FIGS. 11 and 12, the bent portion 102 of the protective cover plate 100 further includes a transition portion 1023 disposed between the first sub-bent portion 1021 and the second sub-bent portion 1022, wherein an arc surface a5, proximal to the flexible display panel 200, of the transition portion 1023 is tangential to the arc surface a1, proximal to the flexible display panel 200, of the first sub-bent portion 1021 and tangential to the arc surface a2, proximal to the flexible display panel 200, of the second sub-bent portion 1022. In this case, by providing the transition portion 1023 between the first sub-bent portion 1021 and the second sub-bent portion 1022 of the protective cover plate 100, and setting the arc surface a5, proximal to the flexible display panel 200, of the transition portion 1023 being tangential to the arc surface a1, proximal to the flexible display panel 200, of the first sub-bent portion 1021 and tangential to the arc surface a2, proximal to the flexible display panel 200, of the second sub-bent portion 1022, in the actual manufacturing process, the presence of the transition portion 1023 prevents the junction, of the arc surface a1, proximal to the flexible display panel 200, of the first sub-bent portion 1021 and the arc surface a2, proximal to the flexible display panel 200, of the second sub-bent portion 1022, from generating a stress concentration point, thereby facilitating the processing of the protective cover plate 100. Further, in the case that a portion of the orthographic projections of the other portions of the second panel portion 202 on the protective cover plate 100 is on the transition portion 1023, the attachment stability performance of the second panel portion 202 with the first sub-bent portion 1021, the transition portion 1023, and the second sub-bent portion 1022 is ensured to be better.

In some embodiments of the present application, as shown in FIGS. 12 and 13, a surface, distal from the body portion 101 of the protective cover plate 100, of the transition portion 1023 of the bent portion 102 is a third table surface a6, which is coplanar with the first table surface a3, distal from the body portion 101, of the first sub-bent portion 1021 and the second table surface a4, distal from the body portion 101, of the second sub-bent portion 1022. The table surfaces are used to form an annular plane. In some embodiments, the annular plane is parallel to a surface a7, proximal to the first panel portion 201 of the flexible display panel 200, of the body portion 101 of the protective cover plate 100. In some embodiments, a width of the third table surface a6, distal from the body portion 101, of the transition portion 1023 of the bent portion 102 gradually increases in an annular direction from the first sub-bent portion 1021 to the second sub-bent portion 1022.

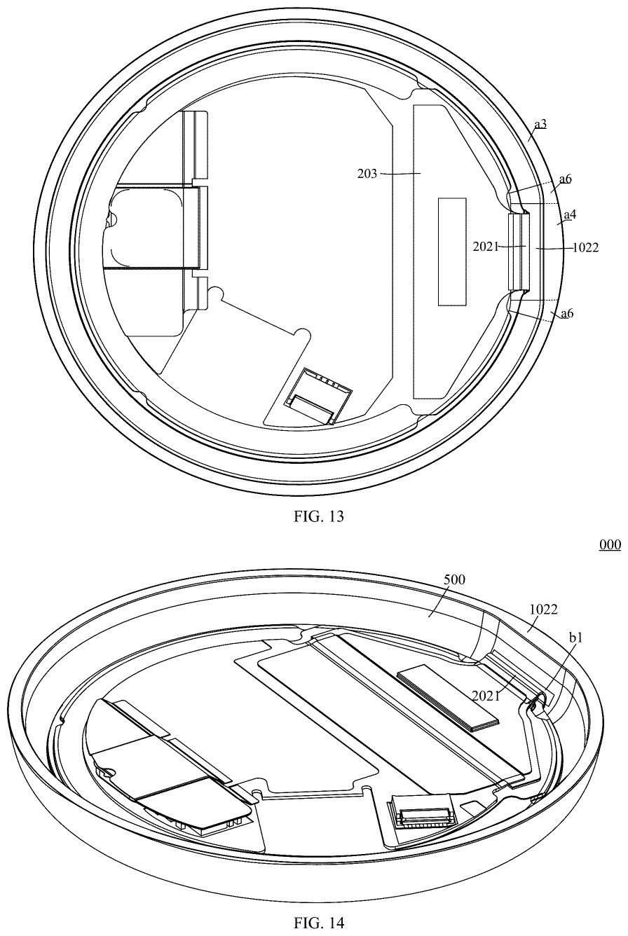

In some embodiments of the present application, reference is made to FIG. 14 and FIG. 15, FIG. 14 being another schematic structural diagram of a display module according to the embodiments of the present application, and FIG. 15 being an exploded schematic diagram of the display module shown in FIG. 14. An avoidance hole b1 is defined in a side, facing the panel bending portion 2021 of the second panel portion 202, of the second sub-bent portion 1022 of the protective cover plate 100. In this case, by providing the avoidance hole b1 on the side of the second sub-bent portion 1022 of the protective cover plate 100 facing the panel bending portion 2021 of the second panel portion 202, in the case that the panel bending portion 2021 of the second panel portion 202 is possible to touch the second sub-bent portion 1022 of the protective cover plate 100, the end of the panel bending portion 2021 enters into the avoidance holes b1, thereby preventing an undesirable phenomenon of fracture caused by the panel bending portion 2021 directly contacting with the arc surface a2, proximal to the flexible display panel 200, of the second sub-bent portion 1022. In some embodiments, the avoidance hole b1 is a through hole or a blind hole, which is not limited in the embodiments of the present application.

In some embodiments of the present application, as shown in FIGS. 4 and 9, the width of the second panel portion 202 of the flexible display panel 200 ranges from 0.1 mm to 1 mm. That is, in the display module 000 of the present application, the range of the width of the flexible display panel 200 that extends into the bent portion 102 of the protective cover plate 100 is 0.1 mm to 1 mm. Within this width range, the flexible display panel 200 is subjected to a smaller force, which in turn can effectively ensure a higher assembly yield of the flexible display panel 200 and the protective cover plate 100. As for the horizontal distance j1 between the panel bending portion 2021 and the protective cover plate 100, the horizontal distance j1 depends on the width of the flexible display panel 200 that extends into the bent portion 102 of the protective cover plate 100 along the direction of j2 (in some embodiments, in the case that the width of the flexible display panel 200 that extends into the bent portion 102 of the protective cover plate 100 increases, the horizontal distance j1 is accordingly reduced).

In some embodiments, as shown in FIGS. 14 and 15, the protective cover plate 100 in the display module 000 includes a central light-transmitting region c1 and an edge shading region c2 at a periphery of the central light-transmitting region c1, wherein at least a portion of the edge shading region c2 is within the bent portion 102 of the protective cover plate 100. The display module 000 further includes a light-absorbent ink layer 500 disposed on a side, proximal to the flexible display panel 200, of the protective cover plate 100, wherein the light-absorbent ink layer 500 is within the edge shading region c2 of the protective cover plate 100. In this case, by providing the light-absorbent ink layer 500 on the side, proximal to the flexible display panel 200, of the protective cover plate 100, and disposing the light-absorbent ink layer 500 within the edge shading region c2 of the protective cover plate 100, the light-absorbent ink layer 500 can provide a good modifying effect on the frame portion of the display module 000 and block the reflected light, thereby improving the display effect of the display module 000. In some embodiments, the light-absorbent ink layer 500 is a black ink layer or an ink layer of other colors, which is not limited in the embodiments of the present application.

In some embodiments of the present application, please refer to FIG. 16, which is an exploded schematic diagram of a display module according to the embodiments of the present application. The display module 000 further includes one or more first alignment structures 600 secured to a side, distal from the protective cover plate 100, of the light-absorbent ink layer 500 and one or more second alignment structures 700 secured to a side, proximal to the protective cover plate 100, of the flexible display panel 200. In some embodiments, the one or more first alignment structures 600 are one-to-one correspondence to the one or more second alignment structures 700. In some embodiments, the first alignment structure 600 and the corresponding second alignment structure 700 thereof are configured to align, prior to attaching the protective cover plate 100 to the flexible display panel 200 in the display module 000, the protective cover plate 100 and the flexible display panel 200. In this case, by providing the first alignment structure 600 on the side, distal from the protective cover plate 100, of the light-absorbent ink layer 500 and the second alignment structure 700 on the side, proximal to the protective cover plate 100, of the flexible display panel 200, the relative attaching position of the flexible display panel 200 to the protective cover plate 100 can be ensured by calibrating the relative position of the first alignment structure 600 and the second alignment structure 700. In actual application, the relative position information of the first alignment structure 600 and the second alignment structure 700 is collected by the photographic device, and then the relative position of the flexible display panel 200 and the protective cover plate 100 is adjusted based on the position information, thereby ensuring the better attachment between the flexible display panel 200 and the protective cover plate 100. In some embodiments, the number of the first alignment structure 600 is one, and the number of the second alignment structure 700 is also one; or, the number of the first alignment structure 600 is multiple, and the number of the second alignment structure 700 is also multiple. In addition, in some embodiments, the multiple first alignment structures 600 are equally spaced along the edge portion of the protective cover plate 100, and the multiple second alignment structures 700 are equally spaced along the edge portion of the flexible display panel. In some embodiments, the number of the first alignment structure 600 is four, and the number of the second alignment structure 700 is also four, which are not limited in the embodiments of the present application.

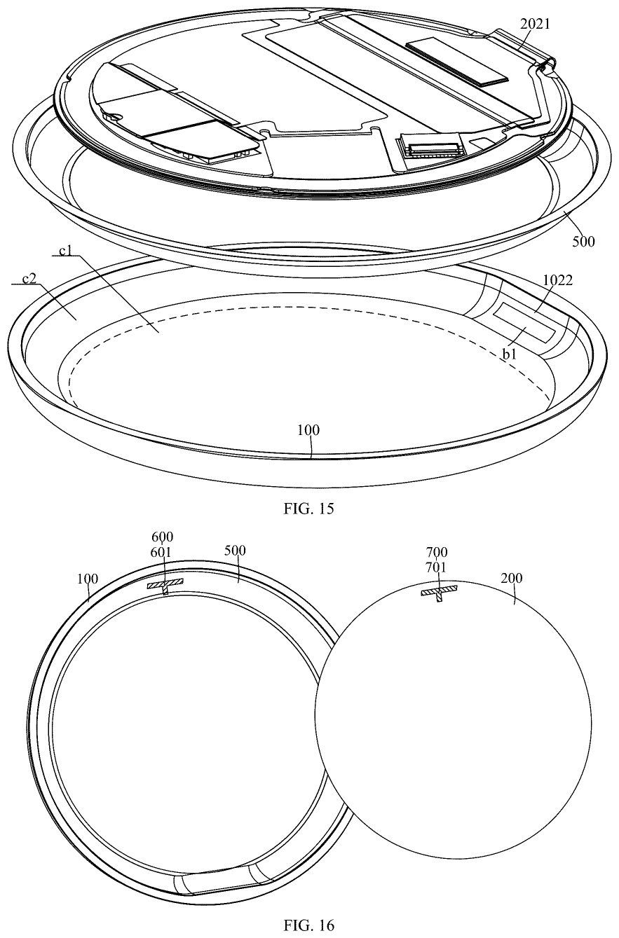

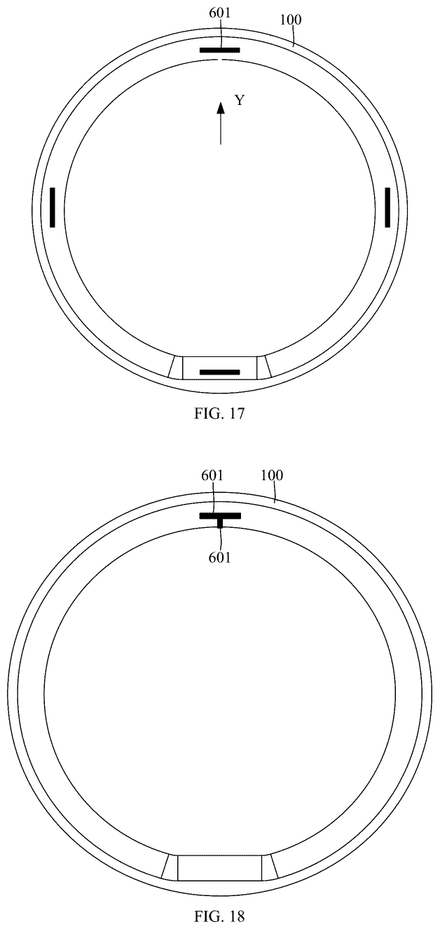

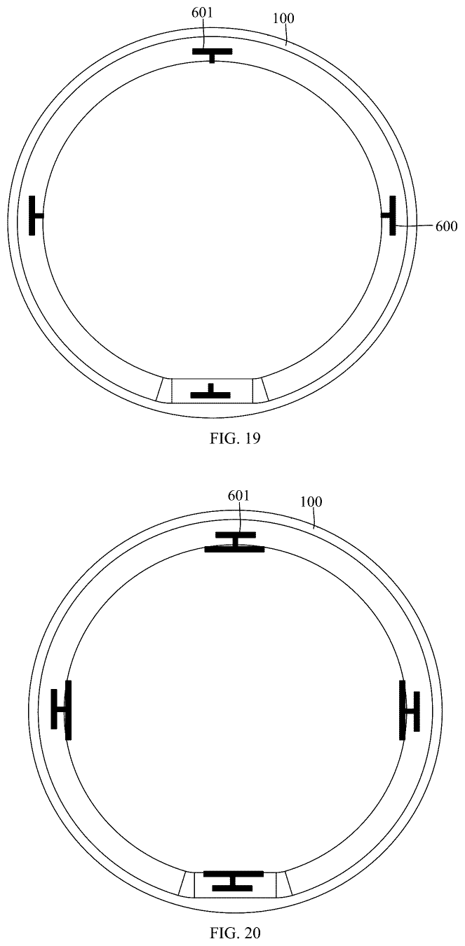

In some embodiments, as shown in FIG. 16, the first alignment structure 600 secured to the side, distal from the protective cover plate 100, of the light-absorbent ink layer 500 includes one or more first alignment strips 601; and the second alignment structure 700 secured to the side, proximal to the protective cover plate 100, of the flexible display panel 200 includes one or more second alignment strips 701, wherein the one or more first alignment strips 601 are one-to-one correspondence to the one or more second alignment strips 701. The first alignment strip 601 and the corresponding second alignment strip 701 thereof are configured for aligning, prior to attaching the protective cover plate 100 to the flexible display panel 200, the protective cover plate 100 and the flexible display panel 200. In some embodiments, reference is made to FIG. 17, which is a schematic diagram of the distribution of a first alignment strip on the protective cover plate according to the embodiments of the present application. The number of the first alignment strip 601 is one, the number of second alignment strip 701 is also one, and a range of an angle between the first alignment strip 601 and the Y-axis direction shown in the figure is from 88 degrees to 92 degrees. In some embodiments, please refer to FIG. 18 and FIG. 19, FIG. 18 is another schematic diagram of the distribution of the first alignment strip on the protective cover plate according to the embodiments of the present application, and FIG. 19 is yet another schematic diagram of the distribution of the first alignment strip on the protective cover plate according to the embodiments of the present application. The number of the first alignment strip 601 is two, and the number of the second alignment strip 701 is also two, the length directions of the two first alignment strips 601 being perpendicular to each other, and the length directions of the two second alignment strips 701 being perpendicular to each other. In some embodiments, please refer to FIG. 20, which is still another schematic diagram of the distribution of the first alignment strip on the protective cover plate according to the embodiments of the present application. The number of first alignment strip 601 is three, and the number of second alignment strip 701 is also three. Therein, two of the first alignment strips 601 are parallel to each other, the other one of the first alignment strips 601 is disposed between these two first alignment strips 601, and the length direction of the one first alignment strip 601 is perpendicular to the length directions of these two first alignment strips 61. Two of the second alignment strips 701 are parallel to each other, the other one of the second alignment strips 701 is disposed between these two second alignment strips 701, and the length direction of the one second alignment strip is perpendicular to the length directions of these two second alignment strips 701. It is to be noted that the shape and number of the first alignment strips 601 in the first alignment structure 600 and the shape and number of the second alignment strips 701 in the second alignment structure 700 are not limited in the embodiments of the present application.

In some embodiments of the present application, the first alignment structure 600 secured to the side, distal from the protective cover plate 100, of the light-absorbent ink layer 500 is made of an ink material, and the color of the first alignment structure 600 is different from the color of the light-absorbent ink layer 500, which facilitates the identification of the first alignment structure on the light-absorbent ink layer 500. In some embodiments, the color of the light-absorbent ink layer 500 is black, and the color of the ink for forming the first alignment structure 600 is w % bite. It is to be noted that in other possible implementations, the light-absorbent ink layer 500 and the first alignment structure 600 can be of other colors, as long as the colors of the light-absorbent ink layer 500 and the first alignment structure 600 are different, which are not limited in the embodiments of the present application. In some embodiments, the second alignment structure 700 fixed on the side, proximal to the protective cover plate 100, of the flexible display panel 200 is made of polyimide (PI) or by metal mold printing, which is not limited in the embodiments of the present application.

In some embodiments, the flexible display panel 200 in the display module 000 includes a display region d1 and a non-display region d2 at a periphery of the display region d1. The boundary of an orthographic projection of the display region d1 of the flexible display panel 200 on the protective cover plate 100 is coincident with the boundary of the central light-transmitting region c1 of the protective cover plate 100. There are typically three possible situations about positions, relative to the protective cover plate 100, of the display region d1 and the non-display region d2 of the flexible display panel 200.

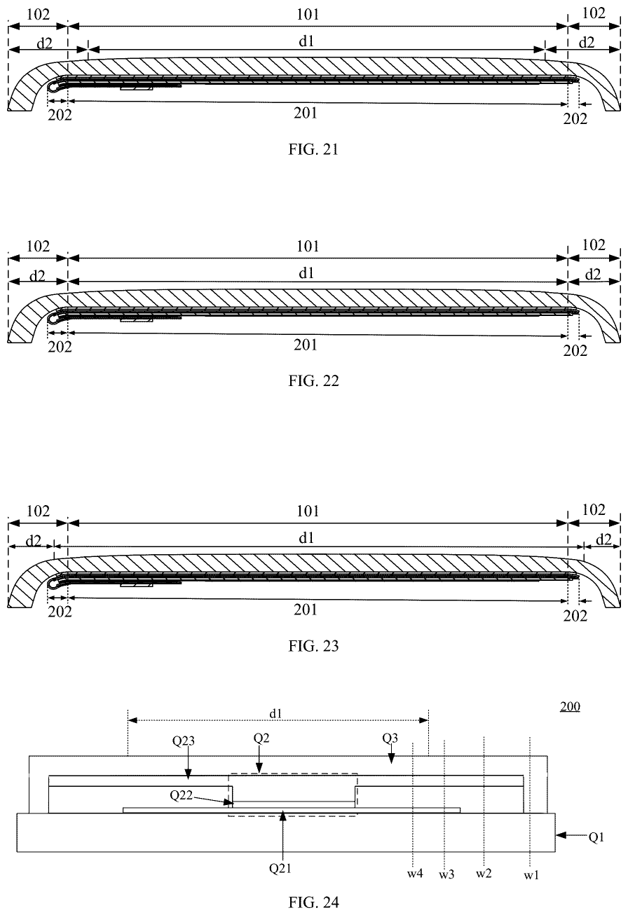

For a first possible situation, referring to FIG. 15 and FIG. 21, FIG. 21 being a cross-sectional view of a display module according to the embodiments of the present application, a portion of the orthographic projection of the non-display region d2 of the flexible display panel 200 on the protective cover plate 100 is within the bent portion 102 of the protective cover plate 100 and another portion is within the body portion 101 of the protective cover plate 100.

For a second possible situation, please refer to FIG. 22, which is another cross-sectional view of the display module according to the embodiments of the present application. The orthographic projection of the non-display region d2 of the flexible display panel 200 on the protective cover plate 100 is entirely within the bent portion 102 of the protective cover plate 10, and the orthographic projection of the display region d1 of the flexible display panel 200 on the protective cover plate 100 is entirely within the body portion 101 of the protective cover plate 100.

For a third possible situation, please refer to FIG. 23, which is yet another cross-sectional view of the display module according to the embodiments of the present application. The orthographic projection of the non-display region d2 of the flexible display panel 200 on the protective cover plate 100 is entirely within the bent portion 102 of the protective cover plate 100, and a portion of the orthographic projection of the display region d1 of the flexible display panel 200 on the protective cover plate 100 is within the bent portion 102 of the protective cover plate 100. In this case, by disposing a portion of the orthographic projection of the display region d1 of the flexible display panel 200 on the protective cover plate 100 within the bent portion 102 of the protective cover plate 100, a picture can be displayed at the bent portion 102 of the protective cover plate 100.

In some embodiments of the present application, reference is made to FIG. 24, which is a schematic diagram of a film layer structure of a flexible display panel according to the embodiments of the present application. The flexible display panel 200 includes a drive backplane Q1, a light-emitting device Q2, and a packaging layer Q3 which are stacked, wherein the packaging layer Q3 is disposed on aside, distal from the drive backplane Q1, of the light-emitting device Q2. In some embodiments, the light-emitting device Q2 includes an anode layer Q21, a light-emitting layer Q22, and a cathode layer Q23 which are stacked, wherein the drive backplane Q1 is electrically connected to the anode layer Q21 of the light-emitting device Q2. In this way, in the case that a driving voltage is applied to the anode layer Q21 by a pixel driving circuit (not shown in the figures) in the driving backplane Q1, and a cathode voltage is applied to the cathode layer Q23, the light-emitting layer Q22, disposed between the anode layer Q21 and the cathode layer Q23, emits light.

In some embodiments, in the case that the orthographic projections of the display region d1 and the non-display region d2 of the flexible display panel 200 on the protective cover plate 100 are at different positions, different film layers in the flexible display panel 200 selectively extend into the bent portion 102 of the protective cover plate 100. In some embodiments, in the case that the boundary of the bending zone corresponds to w1, the packaging layer Q3 in the flexible display panel 200 extends into the bent portion 102 of the protective cover plate 100. In the case that the boundary of the bending zone corresponds to w2, the cathode layer Q23 in the light-emitting device Q2 extends into the bent portion 102 of the protective cover plate 100. In the case that the boundary of the bending zone corresponds to w3, the anode layer Q21 in the light emitting device Q2 extends into the bent portion 102 of the protective cover plate 100. In the case that the boundary of the bending zone corresponds to w4, a portion of the display region d1 of the flexible display panel 200 extends into the bent portion 102 of the protective cover plate 100. It is to be noted that in the case that the flexible display panel 200 further includes other film layers, the other film layers extend into the bent portion 102 of the protective cover plate 100 or be outside the bent portion 102 of the protective cover plate 100 according to actual needs.

In some embodiments of the present application, as shown in FIG. 23, in the case that the orthographic projection of the non-display region d2 of the flexible display panel 200 on the protective cover plate 100 is entirely within the bent portion 102 of the protective cover plate 100, and a portion of the orthographic projection of the display region d1 of the flexible display panel 200 on the protective cover plate 100 is within the bent portion 102 of the protective cover plate 100, a width of the portion, with the orthographic projection being within the bent portion 102 of the protective cover plate, of the display region d1 of the flexible display panel 200 ranges from 0.1 mm to 0.2 mm. In this case, by setting the range of the width of the portion, with the orthographic projection being within the bent portion 102 of the protective cover plate, of the display region d1 of the flexible display panel 200 being 0.1 mm to 0.2 mm, the portion of the flexible display panel 200 is subjected to less force within the above range of width, thereby ensuring the display effect of the display region d1 within the range of width.

In some embodiments, reference is made to FIG. 25, which is a schematic diagram of a protective cover plate assembled with a housing according to the embodiments of the present application. The protective cover plate 100 in the display module 000 includes a first mounting surface e1 and a second mounting surface e2 perpendicular to the first mounting surface e1. In some embodiments, the first mounting surface e1 of the protective cover plate 100 is a surface, distal from the body portion 101, of the bent portion 102 of the protective cover plate 100. The second mounting surface e2 of the protective cover plate 100 is the side surface, distal from the flexible display panel 200, of the protective cover plate 100 in the direction of the display surface of the flexible display panel 200. In some embodiments, both the first mounting surface e1 and the second mounting surface e2 of the protective cover plate 100 are configured for mounting to a housing (not shown in the figures). In some embodiments, both the first mounting surface e1 and the second mounting surface e2 are annular planes. In this way, in the case that the display module 000 is integrated into the display device, the display module is mounted to the housing in the display device through the first mounting surface e1 and the second mating surface e2 of the protective cover plate 100. Therefore, the mounting area between the protective cover plate 100 and the housing is increased, which in turn ensures better mounting precision and higher mounting stabilities between the display module 000 and the housing in the display device. In some embodiments of the present application, the first mounting surface e1 of the protective cover plate 100 is parallel to a surface a7, proximal to the first panel portion 201 of the flexible display panel 200, of the body portion 101 of the protective cover plate 1X).

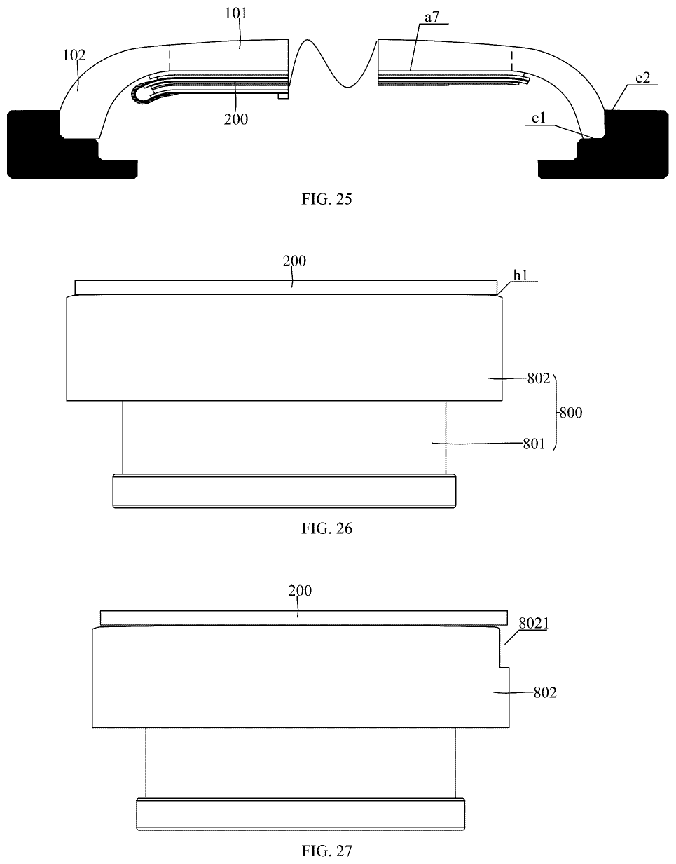

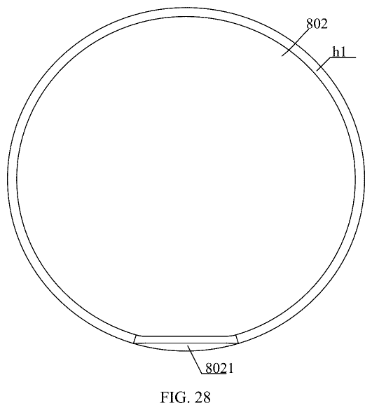

The attachment process of the protective cover plate 100 and the flexible display panel 200 in the display module 000 is described herein: upon the protective cover plate 100 being formed by injection molding, hot bending, and machining processes, the flexible display panel 200 is supported by a support base 800 to facilitate the attachment to the flexible display panel 200. Referring to FIG. 26, FIG. 27, and FIG. 28, FIG. 26 being a front view of a support base for supporting a flexible display panel according to the embodiments of the present application, FIG. 27 being a side view of the support base shown in FIG. 26, and FIG. 28 being a top view of the support base shown in FIG. 26, the support base 800 includes a support base body 801 and a copying portion 802 in a cylindrical shape that is connected to the support base body 801. The flexible display panel 200 is placed on a side, distal from the support base body 801, of the copying portion 802. In some embodiments, the protective cover plate 100 is placed on the light exit side of the flexible display panel 200, and a downward force perpendicular to the protective cover plate 100 is applied to the protective cover plate 100; and the flexible display panel 200 undergoes a copying deformation, within the protective cover plate 100, matching the shape of the protective cover plate 100, such that the second panel portion 202 of the flexible display panel 200 extends into the bent portion 102 of the protective cover plate 100. In addition, in order to ensure that the panel bending portion 2021 of the second panel portion 202 extends smoothly toward the bent portion 102 within the protective cover plate 100 during the attachment process, and to avoid a large compressive stress during the extension process, it is necessary to provide an avoidance region 8021 on the side surface of the copying portion 802. Further, in order to avoid the edge of the copying portion 802 to perform a large compressive stress on the back surface of the flexible display panel 200, a rounded corner h1 is provided on an edge of the side, distal from the support base body 801, of the copying portion 802. In some embodiments, the copying portion 802 of the support base 800 is a cylindrical structure made of a rubber material.

In some embodiments, for the process of manufacturing the protective cover plate 100, there are usually various ways to achieve it, and the present application schematically illustrates the following two optional ways as examples.

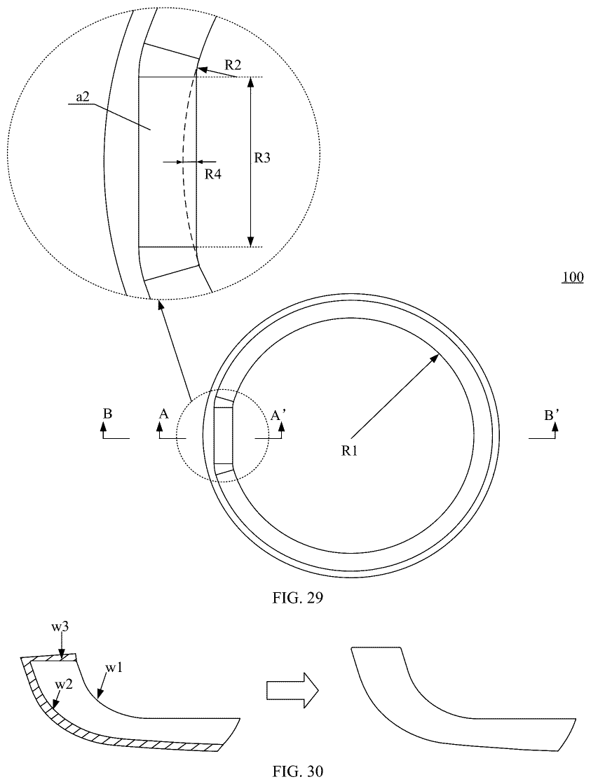

For a first optional way, please refer to FIG. 29 and FIG. 30, wherein FIG. 29 is a top view of a protective cover plate according to the embodiments of the present application, and FIG. 30 is a schematic diagram of a partial structure at A-A′ in FIG. 29. First, taking the bent inner surface w1 (i.e., the arc surface of the bent portion of the protective cover plate) of the blank glass as a reference, the blank glass is bent to become a preliminary shape of the protective cover plate through a hot bending process; and then, the protective cover plate shown in FIG. 29 is acquired by removing the residual w3 on the bent outer surface w2 by a machining process.

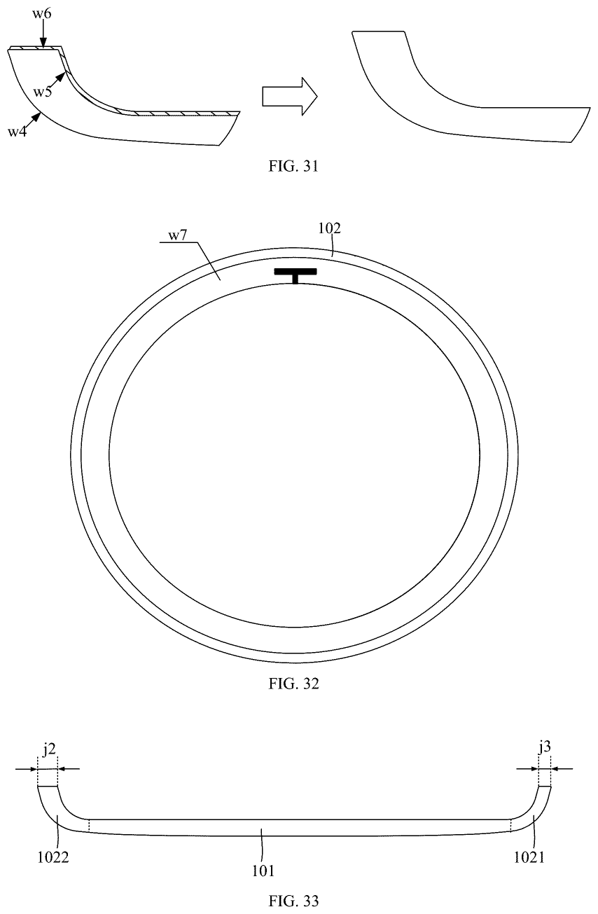

For a second optional way, please refer to FIG. 31, which is another schematic view of the partial structure at A-A′ in FIG. 29. First, taking the bent outer surface w4 (i.e., the surface opposite to the arc surface of the bent portion of the protective cover plate) of the blank glass as a reference, the blank glass is bent to become a preliminary shape of the protective cover plate through a hot bending process; and then, the residual w6 on the bent inner surface w5 is removed through a machining process to acquire the arc surface of the bent portion 102 of the protective cover plate 100 shown in FIG. 29.

It should be noted that, among other possible implementations, reference is made to FIG. 32, which is another top view of the protective cover plate according to the embodiments of the present application. The extending direction of the arc surface w7 of the bent portion 102 of the protective cover plate 100 facing the flexible display panel is all curved, i.e., the arc surfaces at various positions of the bent portion 102 have the same structure.

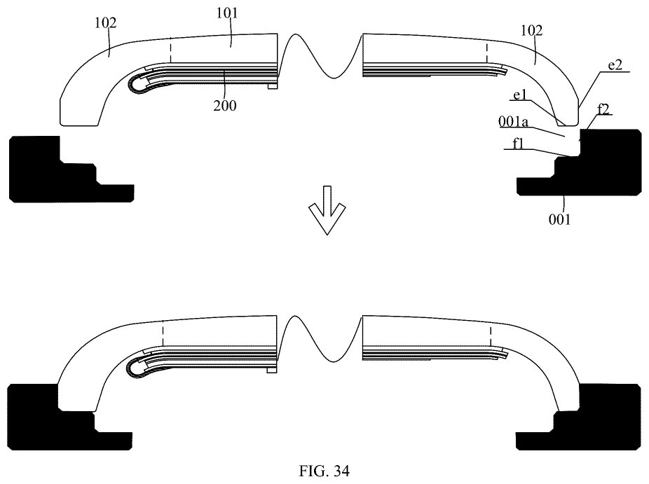

Referring to FIG. 9, FIG. 13, FIG. 29, and FIG. 33, FIG. 33 being a cross-sectional view along B-B′ in FIG. 29, some dimensions associated with some positions in the manufacturing process of the protective cover plate 100 is illustratively described as follows. The radius R1 of the body portion 101 of the protective cover plate 100 depends on the width of the flexible display panel 200 extending into the bent portion of the protective cover plate 100 (i.e., for the protective cover and the flexible display panel with specific sizes, in the case that the width of the flexible display panel extending into the bent portion of the protective cover increases, the radius R1 of the body portion of the protective cover plate accordingly decreases). In order to make the orthographic projection of the panel bending portion 2021 of the second panel portion 202 on the protective cover plate 100 lie entirely within the second sub-bent portion 1022, the width R3 of the arc surface a2 of the second sub-bent portion 1022 of the protective cover plate 100 needs to be greater than the width of the panel bending portion 2021. The maximum distance R4, between a side, proximal to the body portion 101, of the arc surface a2 and the extension position of the boundary of the body portion 101, depends on the width R3 of the arc surface a2 of the second sub-bent portion 1022 (i.e., as the R3 increases, the R4 increases accordingly). Further, in some embodiments, the value of R4 is equal to the difference between the value of the maximum width j2 of the second table surface a4 of the second sub-bending portion 1022 and the maximum width j3 of the first table surface a3 of the first sub-bending portion 1021. In some embodiments, the radius R2 of the transition portion 1023 of the protective cover plate 100 depends on the processing capability of the cover factory.

In summary, the embodiments of the present application provide a display module that includes a protective cover plate and a flexible display panel. The protective cover plate in the display module is disposed on the light exit side of the flexible display panel, a first panel portion of the flexible display panel is attached to a body portion of the protective cover plate, and an orthographic projection of a second panel portion on the protective cover plate is within a bent portion of the protective cover plate, such that the second panel portion of the flexible display panel extends into the bent portion of the protective cover plate. Therefore, upon the flexible display panel being attached to the protective cover plate, the acquired display module has a narrower overall bezel and a larger screen-to-body ratio, which improves the user's experience. In addition, in the case that the display module is integrated into the display device, the overall bezel of the display device is smaller and the decoration effect for the display device is improved.

The embodiments of the present application further provide a display device. In some embodiments, the display device includes a cell phone, a tablet computer, a television, a monitor, a laptop computer, a digital photo frame, a navigator, and any other product having a display function or a device body in a wearable device. In some embodiments, in the case that the display device is a device body in a wearable device, the display device includes a watch or a bracelet, etc. In some embodiments, the display device includes a power supply assembly (not shown in the figures) and a display module 000, wherein the display module 000 is any of the display modules defined in the above embodiments. The power supply assembly is connected to the display module 000 for supplying power to the display module 000 to enable the display module 000 to display an image.

In some embodiments, reference is made to FIG. 34, which is a cross-sectional view of a display device according to the embodiment of the present application. In the case that the protective cover plate in the display module includes a first mounting surface and a second mounting surface, the display device further includes a housing 001, wherein an annular mounting groove 001a is defined in the housing 001. In some embodiments, the mounting groove 001a on the housing 001 includes a bottom surface f1 for connecting to the first mounting surface e1 of the protective cover plate 100 and a side surface 12 for connecting to the second mounting surface e2 of the protective cover plate 100. Thus, in the case that the display module 000 is integrated into the display device, the first mounting surface e1 and the second mounting surface e2 of the protective cover plate 100 are respectively assembled with the bottom surface f1 and the side surface f2 of the housing 001 in the display device. Therefore, the assembly area of the protective cover plate 100 and the housing 001 is increased, which ensures the assembly accuracy and assembly stability of the display module 000 and the housing 001 in the display device.

It is noted that in the accompanying drawings, the dimensions of the layers and regions may be exaggerated for the sake of clarity of the illustrations. Moreover, it is understood that in the case that an element or a layer is referred to as being “on” another element or layer, the element or the layer is directly on the other element or there are intervening layers. Further, it can be understood that in the case that an element or a layer is referred to as being “under” another element or layer, it is directly under the other element, or there are one or more intermediate layers or elements. It is also understood that in the case that a layer or element is referred to as being “between” two layers or elements, the layer or element is the only layer between the two layers or elements, or there is more than one intermediate layer or element. Similar reference signs throughout the description indicate similar elements.

In this application, the terms “first” and “second” are used only for descriptive purposes and are not to be understood as indicating or implying relative importance. The term “plurality” refers to two or more, unless otherwise expressly limited.

The foregoing are only optional embodiments of this application and are not intended to limit this application, and any modifications, equivalent substitutions, improvements, etc., made within the concepts and principles of the application shall be included in the scope of protection of this application.

1. A display module, comprising: a protective cover plate and a flexible display panel; wherein
the protective cover plate comprises a body portion in a shape of a circular plate and a bent portion disposed around the body portion, the bent portion being fixedly connected to an edge of the body portion; and
a light exit side of the flexible display panel faces the protective cover plate, and the flexible display panel comprises a first panel portion attached to the body portion and a second panel portion disposed around the first panel portion, an orthographic projection of the second panel portion on the protective cover plate being within the bent portion.

2. The display module according to claim 1, wherein a boundary of an orthographic projection of the first panel portion on the protective cover plate is coincident with a boundary of the body portion.

3. The display module according to claim 2, wherein both the bent portion and the second panel portion are annular.

4. The display module according to claim 1, wherein at least a part of the second panel portion is attached to the bent portion.

5. The display module according to claim 1, wherein the second panel portion comprises a panel bending portion, and the flexible display panel further comprises a third panel portion fixedly connected to a side, distal from the first panel portion, of the panel bending portion, the third panel portion being configured to be bonded to a drive assembly.

6. The display module according to claim 5, wherein the bent portion comprises a first sub-bent portion and a second sub-bent portion, an extending direction of an arc surface, proximal to the flexible display panel, of the first sub-bent portion being curved, and an extending direction of an arc surface, proximal to the flexible display panel, of the second sub-bent portion being straight;
wherein an orthographic projection of the panel bending portion of the second panel portion on the protective cover plate is at least within the second sub-bent portion, and orthographic projections of other portions of the second panel portion on the protective cover plate are at least within the first sub-bent portion.

7. The display module according to claim 6, wherein a surface, distal from the body portion, of the first sub-bent portion is a first table surface, and a surface, distal from the body portion, of the second sub-bent portion is a second table surface, the first table surface being coplanar with the second table surface, and a width of the first table surface being smaller than a width of the second table surface.

8. The display module according to claim 7, wherein the width of the second table surface gradually decreases in a direction from center to ends of the second table surface.

9. The display module according to claim 6, wherein the bent portion further comprises a transition portion disposed between the first sub-bent portion and the second sub-bent portion;
wherein an arc surface, proximal to the flexible display panel, of the transition portion is tangential to the arc surface, proximal to the flexible display panel, of the first sub-bent portion and tangential to the arc surface, proximal to the flexible display panel, of the second sub-bent portion.

10. The display module according to claim 6, wherein an avoidance hole is defined in a side, facing the panel bending portion, of the second sub-bent portion.

11. The display module according to claim 1, wherein a width of the second panel portion ranges from 0.1 mm to 1 mm.

12. The display module according to claim 1, wherein the protective cover plate comprises a central light-transmitting region and an edge shading region at a periphery of the central light-transmitting region, at least a part of the edge shading region being within the bent portion; and
the display module further comprises a light-absorbent ink layer on a side, proximal to the flexible display panel, of the protective cover plate, the light-absorbent ink layer being within the edge shading region.

13. The display module according to claim 12, further comprising: one or more first alignment structures secured to a side, distal from the protective cover plate, of the light-absorbent ink layer, and one or more second alignment structures secured to a side, proximal to the protective cover plate, of the flexible display panel, the one or more first alignment structures being one-to-one correspondence to the one or more second alignment structures;
wherein the first alignment structure and the corresponding second alignment structure are configured to align the protective cover plate with the flexible display panel prior to attaching the protective cover plate to the flexible display panel.

14. The display module according to claim 13, wherein the first alignment structure is made of an ink material, and a color of the first alignment structure is different from a color of the light-absorbent ink layer.

15. The display module according to claim 12, wherein the flexible display panel comprises a display region and a non-display region at a periphery of the display region, a boundary of an orthographic projection of the display region on the protective cover plate being coincident with a boundary of the central light-transmitting region; wherein
an orthographic projection of the non-display region on the protective cover plate is partially within the bent portion and partially within the body portion; or
the orthographic projection of the non-display region on the protective cover plate is entirely within the bent portion, and an orthographic projection of the display region on the protective cover plate is entirely within the body portion; or
the orthographic projection of the non-display region on the protective cover plate is entirely within the bent portion, and the orthographic projection of the display region on the protective cover is partially within the bent portion.

16. The display module according to claim 15, wherein in the case that the orthographic projection of the non-display region on the protective cover plate is entirely within the bent portion, and the orthographic projection of the display region on the protective cover is partially within the bent portion, a width of the part of the display region with the orthographic projection within the bent portion ranges from 0.1 mm to 0.2 mm.

17. The display module according to claim 1, wherein the protective cover plate comprises a first mounting surface and a second mounting surface perpendicular to the first mounting surface; wherein
the first mounting surface is a surface, distal from the body portion, of the bent portion, and the second mounting surface is a side surface, distal from the flexible display panel, of the protective cover plate in a direction of a display surface of the flexible display panel;
wherein both the first mounting surface and the second mounting surface are configured for mounting to a housing.

18. The display module according to claim 17, wherein the first mounting surface is parallel to a surface, proximal to the first panel portion, of the body portion.

19. A display device, comprising: a power supply assembly and a display module, wherein the power supply assembly is configured to supply power to the display module, and the display module comprises: a protective cover plate and a flexible display panel; wherein
the protective cover plate comprises a body portion in a shape of a circular plate and a bent portion disposed around the body portion, the bent portion being fixedly connected to an edge of the body portion; and
a light exit side of the flexible display panel faces the protective cover plate, and the flexible display panel comprises a first panel portion attached to the body portion and a second panel portion disposed around the first panel portion, an orthographic projection of the second panel portion on the protective cover plate being within the bent portion.

20. The display device according to claim 19, wherein in the case that the protective cover plate comprises a first mounting surface and a second mounting surface, the display device further comprises a housing, wherein an annular mounting groove is defined in the housing, and the mounting groove comprises a bottom surface for connection to the first mounting surface and a side surface for connection to the second mounting surface.
